(19) United States
(12) Patent Application Publication
(10) Pub. No.: US 2008/0265387 A1
(43) Pub. Date: Oct. 30, 2008

(54) SMUDGE RESISTANT COATING FOR ELECTRONIC DEVICE DISPLAYS

(75) Inventors: John J. D'Urso, Chandler, AZ (US); Jeffrey H. Baker, Chandler, AZ (US); Tula Jutarosaga, Chandler, AZ (US)

Correspondence Address: INGRASSIA FISHER & LORENZ, P.C. (MOT), 7010 E. Cochise Road, SCOTTSDALE, AZ, 85253, US

(73) Assignee: MOTOROLA, INC., Schaumburg, IL (US)

(21) Appl. No.: 11/742,217

(22) Filed: Apr. 30, 2007

(51) Int. Cl. H01L 23/02; B05B 5/00

(52) U.S. Cl. 257/678; 427/161; 257/E23.18

(57) ABSTRACT

An apparatus and method is provided for preventing smudges (608) including oils and dust from collecting on a portable electronic device display (110, 150, 200, 300). A plurality of islands (606) are formed on a surface of the display device, each island (606) comprising a transparent material and having a diameter of between 5 and 200 nanometers. Liquid (608) forming on the plurality of islands has a large contact angle (610), increasing the likelihood of the liquid migrating from the display device and thereby removing contaminants therewith.

### FIELD OF THE INVENTION

The present invention generally relates to portable electronic device displays and more particularly to an apparatus and method for preventing smudges including oils and dust from collecting on the displays.

### BACKGROUND OF THE INVENTION

In many portable electronic devices, such as mobile communication devices, displays present information to a user. For example, polymer-dispersed liquid crystal (PDLC) display technology can display video and text information. These optical displays, especially touch panel displays, typically comprise a transparent or a high gloss reflective surface of thermoplastic or glass layer. While these transparent layers have excellent transparency and are physically strong, they suffer both aesthetic and functional degradation due to the build up of oils and other contaminants during use. This is particularly true for the display components of products which receive significant handling, such as personal digital assistants (PDAs) and cell phones. For these displays, any type of fouling is especially undesirable as it tends to be very noticeable to the user and can result in a less than satisfactory viewing experience.

While screen protectors are available for many of these products, they do not offer an optimal solution. Most are based on anti-fouling coatings that reduce smudges, but often become scratched or otherwise degraded, necessitating that the consumer periodically replace them. Some known anti-fouling coatings comprising polymers typically become less transparent due to fabrication methods. Additionally, the fabrication processes for known anti-fouling coatings are unnecessarily complex and expensive. For example, see “Fabrication of Super Water-Repellent Surfaces by Nanosphere Lithography”, Jau-Ye Shiu et al., Mat. Res. Soc. Symp. Proc., Vol. 823, pages W11.4.1-6, 2004.

Accordingly, it is desirable to provide an apparatus and method for preventing smudges including oils and dust from collecting on the portable electronic device displays that does not degrade transparency and is easy to fabricate. Furthermore, other desirable features and characteristics of the present invention will become apparent from the subsequent detailed description of the invention and the appended claims, taken in conjunction with the accompanying drawings and this background of the invention.

### BRIEF SUMMARY OF THE INVENTION

An apparatus and method are provided for preventing smudges including oils and dust from collecting on the portable electronic device displays that does not degrade transparency and is easy to fabricate. The apparatus comprises a plurality of islands comprising a transparent material formed on a surface of a transparent substrate. The islands comprise a diameter of between 5 and 200 nanometers and may be formed as deposited on the substrate or by reflow or other further processing. A thin film of functional groups may be formed on the islands.

### BRIEF DESCRIPTION OF THE DRAWINGS

The present invention will hereinafter be described in conjunction with the following drawing figures, wherein like numerals denote like elements, and

FIG. 1 is a front view of a mobile communication device having a touch screen in accordance with an exemplary embodiment;

FIG. 2 is a partial cross-section of a conventional touch screen taken along line 2-2 of FIG. 1;

FIG. 3 is a cross sectional diagram of a conventional TN/PDLC touch screen taken along line 3-3 of FIG. 1;

FIG. 4 is a timing diagram for a display driver and a capacitive sensor operating the touch screen of FIG. 2 in a conventional manner;

FIG. 5 is a diagram of a liquid drop formed on a known substrate;

FIG. 6 is a diagram of a film formed on a substrate in accordance with a first exemplary embodiment;

FIG. 7 is a schematical representation of a liquid drop formed on the structure of FIG. 6;

FIG. 8 is a picture of the film in accordance with the first embodiment;

FIG. 9 is a picture of the film in accordance with a second exemplary embodiment; and

FIG. 10 is a graph illustrating the contact angle of the exemplary embodiment versus known structures;

### DETAILED DESCRIPTION OF THE INVENTION

The following detailed description of the invention is merely exemplary in nature and is not intended to limit the invention or the application and uses of the invention. Furthermore, there is no intention to be bound by any theory presented in the preceding background of the invention or the following detailed description of the invention.

An integrated solution is disclosed that helps maintain the cleanliness of display surfaces by positioning a layer or layers on the display surface that is resistant to the accumulation of smudges and facilitates the removal of smudges, such as droplets of oil, fatty acids, and other contaminants, resulting in a clean viewing area. The layer or layers comprise a roughness created by metal deposition, anneal, or reflow techniques, which may then be coated with a thin film, e.g., a self-assembled monolayer film, resulting in a low cost anti-smudge film.

The layer or layers are formed in a random manner without the use of lithographic methods. Furthermore, the processing employed is compatible with a high volume manufacturing environment with a large manufacturing base of the needed equipment in existence. In addition to the above named properties, the resulting coating also has high optically transmission and high scratch and abrasion resistance.

Although the apparatus and method described herein may be used with an exposed display surface for any type of electronic device, the exemplary embodiment as shown in FIG. 1 comprises a mobile communication device 100 implementing a touchscreen. While the electronic device shown is a mobile communication device 100, such as a flip-style cellular telephone, the touchscreen can also be implemented in cellular telephones with other housing styles, personal digital assistants, television remote controls, video cassette players, household appliances, automobile dashboards, billboards, point-of-sale displays, landline telephones, and other electronic devices.

The mobile communication device 100 has a first housing 102 and a second housing 104 movably connected by a hinge 106. The first housing 102 and the second housing 104 pivot between an open position and a closed position. An antenna 108 transmits and receives radio frequency (RF) signals for communicating with a complementary communication device such as a cellular base station. A display 110 positioned on the first housing 102 can be used for functions such as displaying names, telephone numbers, transmitted and received information, user interface commands, scrolled menus, and other information. A microphone 112 receives sound for transmission, and an audio speaker 114 transmits audio signals to a user.

A keyless input device 150 is carried by the second housing 104. The keyless input device 150 is implemented as a touchscreen with a display. A main image 151 represents a standard, twelve-key telephone keypad. Along the bottom of the keyless input device 150, images 152, 153, 154, 156 represent an on/off button, a function button, a handwriting recognition mode button, and a telephone mode button. Along the top of the keyless input device 150, images 157, 158, 159 represent a “clear” button, a phonebook mode button, and an “OK” button. Additional or different images, buttons or icons representing modes, and command buttons can be implemented using the keyless input device. Each image 151, 152, 153, 154, 156, 157, 158, 159 is a direct driven pixel, and this keyless input device uses a display with aligned optical shutter and backlight cells to selectively reveal one or more images and provide contrast for the revealed images in both low-light and bright-light conditions.

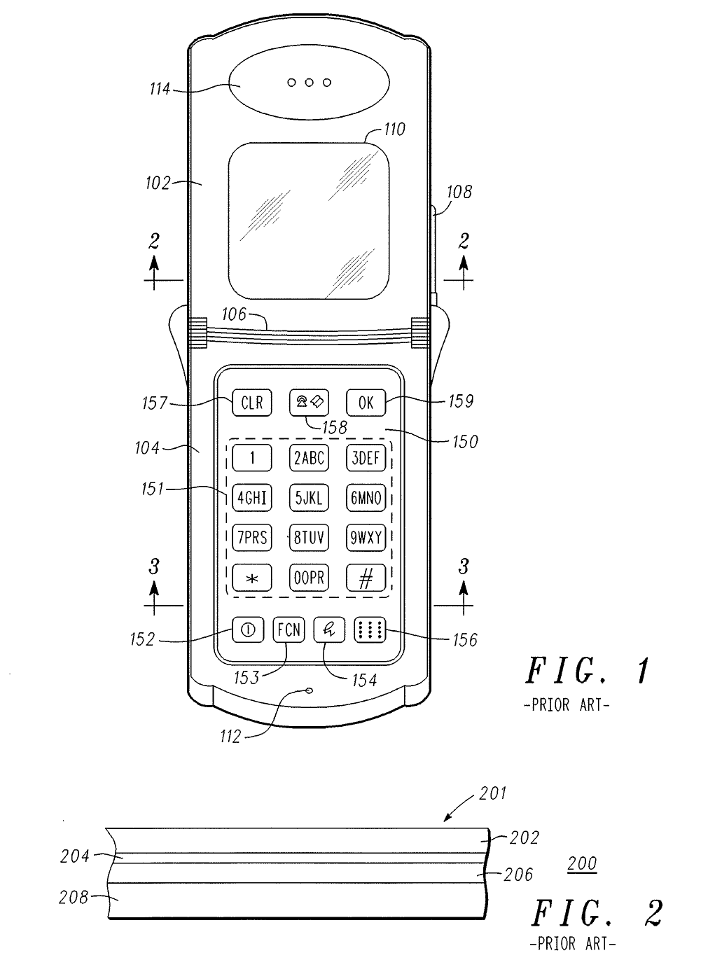

Referring to FIG. 2, a cross section of a conventional touchscreen 200 is depicted that is usable for either the display 110 or the keyless input device 150 with the cross-section, for example, being a portion of a view taken along line 2-2 of FIG. 1. The conventional display 200 is a stack with a user-viewable and user-accessible face 201 and multiple layers below the face 201, including a transparent cover 202, a thin transparent conductive coating 204, a substrate 206, and an imaging device 208. The transparent cover 202 provides an upper layer viewable to and touchable by a user and may provide some glare reduction. The transparent cover 202 also provides scratch and abrasion protection to the layers 204, 206, 208 contained below.

The substrate 206 protects the imaging device 208 and typically comprises plastic, e.g., polycarbonate or polyethylene terephthalate, or glass, but may comprise any type of material generally used in the industry. The thin transparent conductive coating 204 is formed over the substrate 206 and typically comprises a metal or an alloy such as indium tin oxide or a conductive polymer.

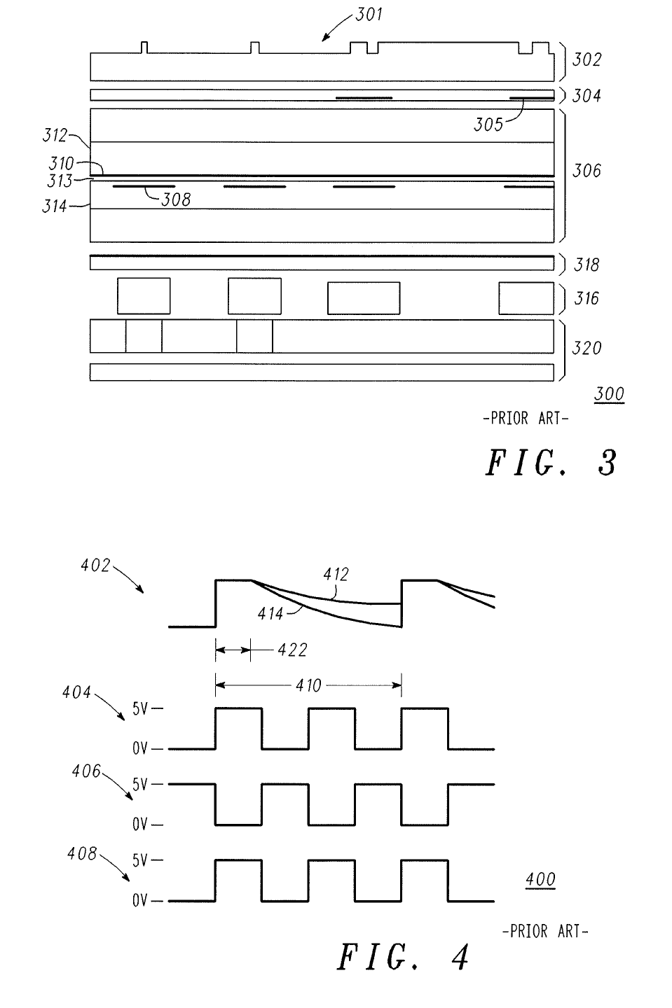

Referring to FIG. 3, a cross section of a conventional display 300 is depicted with aligned optical shutter and backlight cells and is usable for the display 110 of FIG. 1 with the cross-section being a portion of a view taken along line 3-3 of FIG. 1. The conventional display 300 is a stack with a user-viewable and user-accessible face 301 and multiple layers below the face 301, including a transparent cover 302 and a capacitive sensor layer 304 with an indium-tin oxide (ITO) electrode 305. The transparent cover 302 provides an upper layer viewable to and touchable by a user and may provide some glare reduction. The capacitive sensor layer 304 senses touchscreen inputs on the transparent cover 302 of the display 300. Beneath the capacitive sensor layer 304 is a twisted nematic (TN) stack layer 306 including a TN backplane electrode 310 and TN segment electrodes 308 between two substrates 312, 314 for providing the optical shutter operation of the display 300. The TN backplane electrode 310 and TN segment electrodes 308 are formed of indium-tin oxide (ITO) material to provide both transparency and electrical conductivity for operation of the TN stack. Also, while the TN backplane electrode 310 is depicted above the TN segment electrodes 308, a TN stack layer 306 having the TN backplane electrode 310 below the TN segment electrodes 308 would function similarly.

The TN stack layer 306 utilizes, for example, twisted nematic liquid crystal (TNLC) display technology employing TN optical shutter material in an optical shutter layer 313 and the TN segment electrodes 308 to provide optical shutter operation. While TNLC technology is described herein for the optical shuttering operation, the optical shutter layer 313, sandwiched between the TN backplane electrodes 310 and the TN polymer segment electrodes 308, can alternatively be made using TNLC technology (such as twisted nematic or super twisted nematic liquid crystals), polymer-dispersed liquid crystal (PDLC) technology, ferro-electric liquid crystal technology, electrically-controlled birefringent technology, optically-compensated bend mode technology, guest-host technology, and other types of light modulating techniques which use optical shutter material 313 such as TN polymer material, PDLC material, cholesteric material, or electro-optical material. The electric field created by the electrodes 308, 310 alter the light transmission properties of the TNLC optical shutter material 313, and the pattern of the TN segment electrode layer 308 defines pixels of the display. These pixels lay over the images 151, 152, 153, 154, 156, 157, 158, 159 shown in FIG. 1. In the absence of the electric field, the liquid crystal material and dichroic dye in the TNLC material 313 are randomly aligned and absorb most incident light. In the presence of the electric field, the liquid crystal material and dichroic dye align in the direction of the applied field and transmit substantial amounts of incident light. In this manner, a pixel of the TNLC cell can be switched from a relatively non-transparent state to a relatively transparent state. Each pixel can be independently controlled to be closed-shuttered or open-shuttered, depending on the application of an electric field, and the pixels act as “windows” with optical shutters that can be opened or closed, to reveal images underneath (e.g. images 151, 152, 153, 154, 156, 157, 158, 159).

Beneath the TN stack layer 306 is an electroluminescent (EL) stack layer 316 separated from the TN stack layer 306 by an ITO ground layer 318. The EL stack layer 316 includes a backplane and electrodes which provide backlight for operation of the display 300 in both ambient light and low light conditions by alternately applying a high voltage level, such as one hundred volts, to the backplane and electrode. The ITO ground layer 318 is coupled to ground and provides an ITO ground plane 318 for reducing the effect on the capacitive sensor layer 304 of any electrical noise generated by the operation of the EL stack layer 316 or other lower layers within the display 300. Beneath the EL stack layer 316 is a base layer 320 which may include one or more layers such as a force sensing switch layer and/or a flex base layer. The various layers 302, 304, 306, 318, 316 and 320 are adhered together by adhesive layers applied therebetween.

Conventional operation of the display 300 is illustrated in FIG. 4, wherein the charge 402 from the capacitive sensor layer 304, the voltage 404 of the TN backplane 310 and the voltages 406, 408 of first and second portions of the TN segment electrodes 308 are depicted. To perform capacitive sensing during a period 410, a charging voltage is provided to the ITO electrode 305 of the capacitive sensor layer 304 for a first portion 422 of the period 410. After the charging voltage is removed from the electrode 305, the charge 402 has two different decay profiles 412, 414 depending on whether a user's touch is detected on the display 300. In an electrically noisy environment, the signal-to-noise ratio (SNR) of the capacitive sensing (i.e., of the voltage of the detectable charge), where the charge is the multiple of the capacitance (determined from a distance of user's finger from the face 301) times the voltage thereof, is small, thereby complicating detection of touchscreen inputs. The ITO ground plane layer 318 provides some isolation between the high voltage EL backlight layer 316 and the low voltage TN stack layer 306, thereby increasing the SNR of the capacitive sensing.

During the same time period 410, the voltages 404, 406, 408 supplied to the TN backplane 310 and the TN segment electrodes 308 are switched between a positive voltage, typically about five volts, and zero volts. The voltage 406 of the portion of the TN segment electrodes 308 that are turned “on” to render corresponding portions of the display 300 over such portion of the TN segment electrodes 308 relatively transparent are switched opposite to the voltage 404 of the TN backplane 310 (i.e., when the voltage 304 of the TN backplane is high, the voltage 406 of the “on” portion of the TN segment electrodes 308 is low). Conversely, the voltage 408 of the portion of the TN segment electrodes 308 that are turned “off” optically shutter corresponding portions of the display 300 over such portion of the TN segment electrodes 308 because their voltage is switched in the same manner as the voltage 404 of the TN backplane 310. It can be seen from FIG. 4 that during period 410, the voltages 406, 408 supplied to the TN segment electrodes 308 and the TN backplane 310 are high approximately fifty percent of the time period 410.

Those skilled in the art will appreciate that other types of imaging devices 200, 300 may be utilized as exemplary embodiments, including, for example, transmissive, reflective or transflective liquid crystal displays, cathode ray tubes, micromirror arrays, and printed panels.

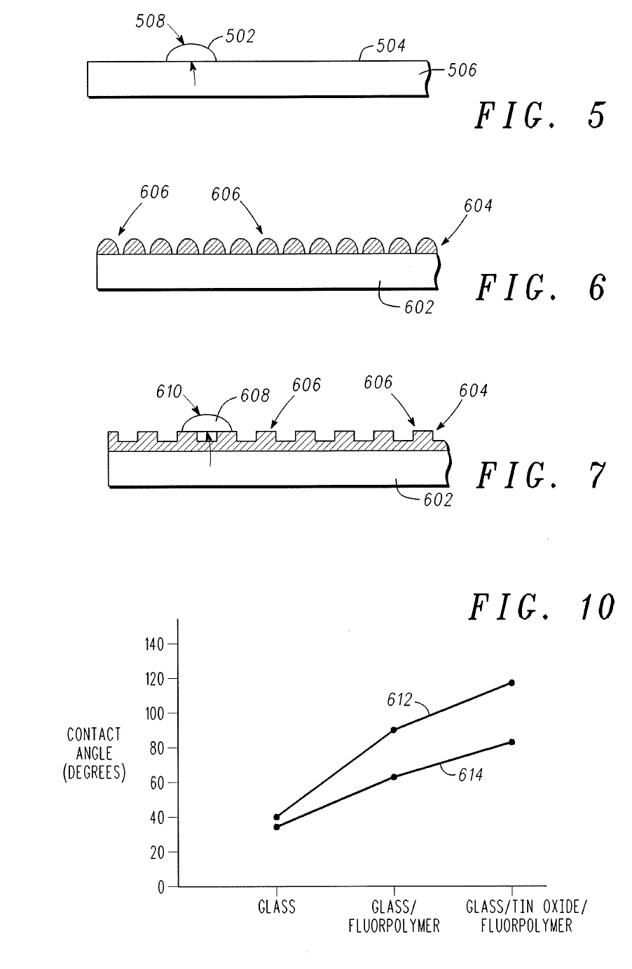

Referring to FIG. 5, when a smudge 502, such as a drop of water or oil, forms on a surface 504 of a substrate 506, a contact angle 508 is formed. The contact angle is the angle at which the smudge 502 meets the surface 504, with the magnitude of the angle depending on characteristics of the smudge 502 and the surface 504. These characteristics include a thermodynamic equilibrium between a liquid phase of the droplet, a solid phase of the substrate, and a gas/vapor phase of the ambient atmosphere and an equilibrium concentration of the liquid vapor. At equilibrium, the chemical potential in the three phases will be equal. The contact angle 508 for water on a flat surface, e.g., glass, typically is approximately forty degrees. Surfaces are commonly characterized by the water contact angle with surfaces having water contact angles below 90 degrees termed “hydrophilic” and surfaces having water contact angles of 90 degrees or greater termed “hydrophobic”. An analogous set of definitions is created via characterization with oleic acid with surfaces having oleic acid contact angles below 90 degrees termed “oleophilic” and surfaces having water contact angles of 90 degrees or greater termed “oleophobic”.

The highest water contact angle observed on a flat surface is approximately 120 degrees. It has long been recognized that some surfaces that are not flat exhibit water contact angles much greater than 120 degrees, however. For instance, it is known in nature that the lotus plant that grows in muddy rivers and lakes has leaves that remain clean. The microscopic structure and surface chemistry of the lotus leaves prevent them from getting wet. Water drops roll off of the leafs surface, taking mud and contaminants (smudges) with them (called the lotus effect). The leaf of the lotus plant contains small “bumps” that change the contact angle to a larger magnitude. This larger contact angle is indicative of low surface attraction which allows the water to roll off of the leaf.

“Cassie's law” describes how roughing up a surface increases the effective contact angle θ, for a liquid on a surface. Cassie's law states:

cos θ_{c}=γ₁ cos θ₁+γ₂ cos θ₂

where θ₁=contact angle for component 1 with areal fraction γ₁, and

θ₂=contact angle for component 2 with areal fraction γ₂.

When the second component is air with a contact angle of 180 degrees and since cosine (180)=−1, the equation becomes:

cos θ_{c}=γ₁(cos θ₁+1)−1

Therefore, when γ₁ is small and θ₁ is large, a large contact angle θ_{c} is provided.

“Superhydrophobic” materials with water contact angles in excess of 150 degrees are very well known. Many methods of fabricating them have been described. Such surfaces are very resistant to maintaining water thereon. It is very important to realize, however, that such surfaces are not necessarily oleophobic or is there necessarily a correlation between water and oleic acid contact angles. For example, surfaces have been created which have water contact angles greater than 150 degrees but oleic acid contact angles of less than 10 degrees. Understanding this distinction is very important since flat surfaces typically do not exhibit oleophobic behavior.

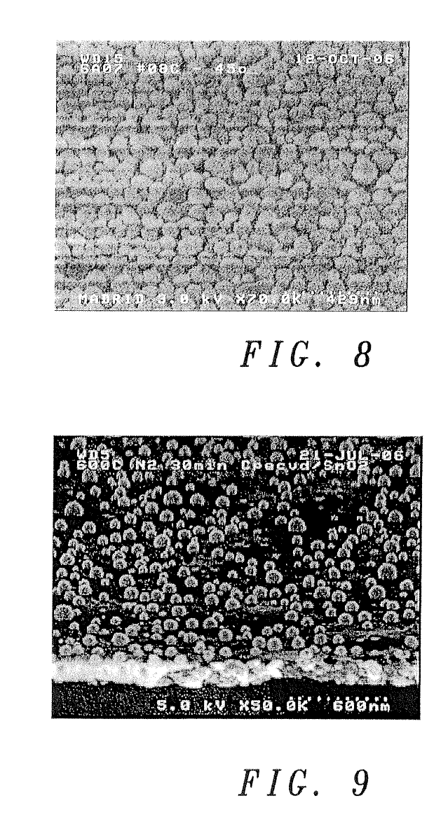

In accordance with the exemplary embodiments described herein, an apparatus and method of creating a layer which is both hydrophobic and oleophobic that helps prevent smudges, including oils and dust, from collecting on the display surfaces is shown in FIG. 6 and includes a layer 604 formed on a substrate 602. The substrate comprises a transparent material such as glass or a polymer (plastic). The layer 604 comprises a transparent material, preferably a metal such as tin, and is deposited using physical vapor deposition to form a plurality of thin islands 606, or bumps. Portions of the substrate 602 may be observed between the islands 606, or the substrate 602 may be coated, partially or completely, with the tin material as shown in the schematical representation of FIG. 7. Alternatively, a thicker layer 604 of the transparent metal may be deposited, heated in an oxygen free ambient, and allowed to reflow. Regardless of which process is used, conversion to an oxide via an anneal in oxygen, or other oxidation technique, yields a film which is transparent. A picture of a film formed in this manner is shown in FIG. 8. Each island 606 is preferably about 50 nanometers across (diameter), but may have a diameter in the range of 5 to 200 nanometers. The distance between each island 606 is preferably about 50 nanometers. The height of the islands preferably is less than 100 nanometers to maintain transparency.

In another embodiment, layers utilizing appropriate thicknesses of tin oxide covered with diamond-like carbon, or tin oxide covered with a layer of tin covered with a layer of diamond-like like carbon will grow “nodules” when annealed in nitrogen, resulting in structures similar to that shown in the picture shown in FIG. 9.

These structures of FIGS. 8 and 9 can then be made to have a low surface energy by coating with another layer containing the appropriate functional groups. Preferred groups include alkyl- and fluoro-groups. Deposition can by be done in many ways including by vapor deposition, dipping, and spraying. A wide variety of chemicals can be used, but those forming self assembled monolayers are preferred because they can coat without filling in the topography, can bond with the surface for good durability, and can allow good optical transmission. Suitable chemicals for coating the structure above include, for example, 1H, 1H, 2H, 2H-perfluorodecyltriethoxysilane.

Referring again to FIG. 7, when a drop 608 forms on the islands 606, it will “bulge” out at its sides, resulting in a larger contact angle 610. FIG. 10 shows the contact angle for each of a glass substrate, a glass substrate covered with a fluorpolymer, and in accordance with the present invention, a glass substrate covered with tin oxide islands and a fluorpolymer. For each of the three surfaces, line 612 illustrates the contact angle for water and line 614 illustrates the contact angle for oleic acid. It is seen that the glass substrate covered with tin oxide islands and a fluorpolymer provides a larger contact angle for water and oleic acid, than either of the two known methods and results in a surface which is both hydrophobic and oleophobic.

These various exemplary embodiments provide a transparent cover to the display that is abrasion resistant and prevents smudges, including oils, dust, and other contaminants from collecting on the display's surface.

While at least one exemplary embodiment has been presented in the foregoing detailed description of the invention, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention, it being understood that various changes may be made in the function and arrangement of elements described in an exemplary embodiment without departing from the scope of the invention as set forth in the appended claims.

1. An electronic device comprising:
a housing;
a display device positioned within the housing and comprising a transparent substrate having a surface viewable outside of the housing;
electronic circuitry to present information to the display device; and
a plurality of bumps comprising a transparent material formed on the surface.

2. The electronic device of claim 1 wherein each of the bumps comprises a diameter of between 5.0 and 200.0 nanometers.

3. The electronic device of claim 1 wherein each of the bumps comprises a diameter of approximately 50 nanometers and is spaced approximately 50 nanometers apart from adjacent bumps.

4. The electronic device of claim 1 wherein each of the bumps comprises a height from the surface of less than 100 nanometers.

5. The electronic device of claim 1 further comprising a film having functional groups formed on the plurality of bumps.

6. The electronic device of claim 5 wherein the film comprises one of alkyl- or fluoro-groups.

7. The electronic device of claim 5 wherein the film comprises a self-assembled monolayer.

8. An electronic device comprising:
a display device comprising a transparent material having a surface susceptible to receiving contaminants, the transparent material comprising a plurality of islands formed on the surface, each island having a diameter of between 5 and 200 nanometers; and
electronic circuitry coupled to the display device for presenting information thereto.

9. The electronic device of claim 8 wherein each of the islands comprise a diameter of approximately 50 nanometers.

10. The electronic device of claim 8 wherein each of the islands comprise a height from the surface of less than 100 nanometers.

11. The electronic device of claim 8 further comprising a film having functional groups formed on the plurality of islands.

12. The electronic device of claim 8 wherein the film comprises one of alkyl- or fluoro-groups.

13. A method of manufacturing an electronic display device having a film that reduces the likelihood of contaminants from being positioned on a viewing area of a transparent surface of a substrate, comprising:
depositing a film of a material on the surface of the substrate to form a plurality of islands; and
oxidizing the film to provide transparency.

14. The electronic device of claim 13 wherein the depositing step comprises:
heating the film; and
reflowing the film to form the plurality of islands.

15. The method of claim 13 wherein the depositing step comprises one of vapor deposition, dipping, and spraying.

16. The method of claim 13 wherein the depositing step comprises forming islands having a diameter of between 5 and 200 nanometers.

17. The method of claim 13 wherein the depositing step comprises forming islands having a diameter of approximately 50 nanometers.

18. The method of claim 13 wherein the depositing step comprises forming islands having a height from the surface of less than 100 nanometers.

19. The method of claim 13 wherein the depositing step comprises forming a self assembled monolayer.

20. The method of claim 13 wherein the depositing step comprises forming a film having functional groups formed on the plurality of islands.

21. The method of claim 13 wherein the depositing step comprises forming islands having a one of alkyl- or fluoro-groups formed thereon.
